(19) United States
(12) Patent Application Publication
(10) Pub. No.: US 2015/0294704 A1
(43) Pub. Date: Oct. 15, 2015

(54) ELECTRONIC DEVICE

(71) Applicant: SK hynix Inc., Icheon-Si (KR)

(72) Inventors: Ji-Hyae Bae, Icheon-Si (KR); Yong-Ho Kim, Icheon-Si (KR); Min-Hye Lee, Icheon-Si (KR)

(21) Appl. No.: 14/484,236

(22) Filed: Sep. 11, 2014

(30) Foreign Application Priority Data
Apr. 10, 2014 (KR) 10-2014-0043009

(51) Int. Cl. G11C 11/16; G11C 13/00

(52) U.S. Cl. CPC G11C 11/1673; G11C 13/004; G11C 13/0069; G11C 13/003; G11C 11/1659; G11C 11/1675; G11C 2013/0054; G11C 2013/0078

(57) ABSTRACT

Provided is an electronic device including a semiconductor memory unit. The semiconductor memory unit may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein.

### CROSS-REFERENCE TO RELATED APPLICATIONS

This patent document claims priority of Korean Patent Application No. 10-2014-0043009, entitled “ELECTRONIC DEVICE” and filed on Apr. 10, 2014, which is incorporated herein by reference in its entirety.

### TECHNICAL FIELD

This patent document relates to memory circuits or devices and their applications in electronic devices or systems.

### BACKGROUND

Recently, as electronic devices or appliances trend toward miniaturization, low power consumption, high performance, multi-functionality, and so on, there is a demand for semiconductor devices capable of storing information in various electronic devices or appliances such as a computer, a portable communication device, and so on, and research and development for such electronic devices have been conducted. Examples of such semiconductor devices include semiconductor devices which can store data using a characteristic that they are switched between different resistance states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device which includes two variable resistance elements in each storage cell so as to increase margin and speed of read and write operations.

In one aspect, an electronic device including a semiconductor memory unit is provided. The semiconductor memory unit may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein.

In some implementations, during a read operation, the semiconductor memory unit compares a current flowing in the first variable resistance element with a current flowing in the second variable resistance element.

In some implementations, each of the first and second variable resistance elements has a resistance value which is switched between first and second resistance values when a switching current is switched between a first current direction and a second, opposite current direction when flowing through each variable resistance element.

In some implementations, when the first value is stored in the storage cell, the semiconductor memory unit passes the switching current in the first direction through the first variable resistance element and passes the switching current in the second, opposite direction through the second variable resistance element, and when the second value is stored in the storage cell, the semiconductor memory unit passes the switching current in the second direction through the first variable resistance element and passes the switching current in the first direction through the second variable resistance element.

In some implementations, the semiconductor memory unit further includes: one or more word lines each coupled to apply a voltage to select a corresponding storage cell among the one or more storage cells; one or more first bit lines each coupled to one end of a corresponding storage cell among the one or more storage cells; and one or more second bit lines each coupled to the other end of a corresponding storage cell among the one or more storage cells.

In some implementations, each storage cell includes: a first selecting element coupled between the first bit line and one end of the first resistance variable element, and operable to be turned on or off in response to the voltage of a corresponding word line; a second selecting element coupled between the second bit line and one end of the second resistance variable element, and operable to be turned on or off in response to the voltage of the corresponding word line; and a sinking element coupled to the other ends of the first and the second variable resistance elements, and operable to be turned on or off to allow for passage a current.

In some implementations, during the write operation, the first and second selecting elements of a selected storage cell among the one or more storage cells are turned on and the sinking element of the selected storage cell is turned off, when the first value is stored in the selected storage cell, the switching current flows from the second bit line to the first bit line through the selected storage cell, and when the second value is stored in the selected storage cell, the switching current flows from the first bit line to the second bit line through the selected storage cell.

In some implementations, the semiconductor memory unit further includes an access control unit that provides a switching current to a selected storage cell during a write operation in a manner that the direction of the switching current changes depending on data to be written to the selected storage cell.

In some implementations, during the read operation, the first and second selecting elements of a selected storage cell among the one or more storage cells are turned on and the sinking element of the selected storage cell is turned on, a current flows between the first bit line and the source line through the selected storage cell, and a current flows between the second bit line and the source line through the selected storage cell.

In some implementations, the semiconductor memory unit further includes an access control unit, that provides, during a read operation, a first read current and a second read current flowing through the first and the second variable resistance elements, respectively, and determines data stored in the storage cell by comparing the first read current with the second read current.

In some implementations, the semiconductor memory unit comprises one or more amplification units each coupled between the first and second bit lines, and suitable for driving the second bit line to the inverse voltage of a voltage corresponding to data of the first bit line and driving the first bit line to the inverse voltage of a voltage corresponding to data of the second bit line.

In some implementations, the semiconductor memory unit further includes a write control unit suitable for driving the first and second bit lines to a voltage which is determined according to data to be written to a selected storage cell among the plurality of storage cells, and not driving the first and second bit lines when the data stored in the selected storage cell is equal to the data to be written to the selected storage cell.

In some implementations, the semiconductor memory unit further includes a write control unit suitable for driving the first and second bit lines to a voltage which is determined according to data to be written to a selected storage cell among the plurality of storage cells only when the data stored in the selected storage cell is not equal to the data to be written to the selected storage cell.

In some implementations, each of the first and second variable resistance elements includes a metal oxide, a phase change material, or a structure having two magnetic layers and a tunnel barrier layer interposed therebetween.

In some implementations, the electronic device further includes a microprocessor which includes a control unit that is configured to receive a signal including a command from an outside of the microprocessor, and performs extracting, decoding of the command, or controlling input or output of a signal of microprocessor; and an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the variable resistance element is part of the memory unit in the microprocessor.

In some implementations, the electronic device further includes a processor which includes a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the variable resistance element is part of the cache memory unit in the processor.

In some implementations, the electronic device further includes a processing system which includes a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between the processor, the auxiliary memory device or the main memory device and the outside, wherein the semiconductor memory unit that includes the variable resistance element is part of the auxiliary memory device or the main memory device in the processing system.

In some implementations, the electronic device further includes a data storage system which includes a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the variable resistance element is part of the storage device or the temporary storage device in the data storage system.

In some implementations, the electronic device further includes a memory system which includes a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the variable resistance element is part of the memory or the buffer memory in the memory system.

In another aspect, an electronic device is provided to include a semiconductor memory unit that includes bit lines; bit line bars; a plurality of word lines; a plurality of first selecting elements each having one end coupled to a corresponding bit line, and operable to be turned on or off in response to the voltage of a corresponding word line; a plurality of first variable resistance elements each having one end coupled to the other end of a corresponding first selecting element; a plurality of second selecting elements each having one end coupled to a corresponding bit line bar, and operable to be turned on or off in response to the voltage of a corresponding word line; and a plurality of second resistance variable elements each having one end coupled to the other end of a corresponding second selecting element and the other end coupled to the other end of a corresponding first resistance variable element, wherein each of the first variable resistance elements and the second variable resistance elements has either a first resistance value or a second resistance value and the resistance value of each of the first variable resistance elements and the second variable resistance elements changes depending on a direction of a switching current flowing through each of the first variable resistance elements and the second variable resistance elements.

In some implementations, the semiconductor memory unit activates a selected word line among the plurality of word lines, and pass a current between the bit line and the bit line bar through first and second resistance variable elements corresponding to the activated word line, during a write operation.

In some implementations, during a read operation, the semiconductor memory unit activates a selected word line among the plurality of word lines, pass a first read current between the bit line and a first variable resistance element corresponding to the activated word line, pass a second read current between the bit line bar and a second variable resistance element corresponding to the activated word line, and compare the first read current to the second read current.

In some implementations, the semiconductor memory unit further includes a plurality of sinking elements each coupled to a pair of first and second variable resistance elements that are located next to each other and are connected to each other, and operable to be turned on to apply a read voltage to the first resistance variable element and the corresponding paired second resistance variable element during the read operation.

In some implementations, the semiconductor memory unit further includes one or more amplification units each coupled between a corresponding bit line and a corresponding bit line bar, and suitable for driving the bit line bar to the opposite voltage of a voltage corresponding to data of the bit line and driving the bit line to the opposite voltage of a voltage corresponding to data of the bit line bar.

In some implementations, the semiconductor memory unit further includes one or more write control units suitable for driving a bit line and a bit line bar, corresponding to first and second resistance variable elements which are selected among the plurality of first resistance variable elements and the plurality of second resistance variable elements, to a voltage which is determined according to data to be written to the selected first and second resistance variable elements, and not driving the bit line and the bit line bar corresponding to the selected first and second resistance variable elements when data stored in the selected first and second resistance variable elements are equal to data to be written to the selected first and second resistance variable elements.

In some implementations, the electronic device further includes a microprocessor which includes a control unit that is configured to receive a signal including a command from an outside of the microprocessor, and performs extracting, decoding of the command, or controlling input or output of a signal of microprocessor; and an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the variable resistance element is part of the memory unit in the microprocessor.

In some implementations, the electronic device further includes a processor which includes a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the variable resistance element is part of the cache memory unit in the processor.

In some implementations, the electronic device further includes a processing system which includes a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between the processor, the auxiliary memory device or the main memory device and the outside, wherein the semiconductor memory unit that includes the variable resistance element is part of the auxiliary memory device or the main memory device in the processing system.

In some implementations, the electronic device further includes a data storage system which includes a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the variable resistance element is part of the storage device or the temporary storage device in the data storage system.

In some implementations, the electronic device further includes a memory system which includes a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the variable resistance element is part of the memory or the buffer memory in the memory system.

In another aspect, an electronic device is provided to include a semiconductor memory unit that includes a first storage unit having a first resistance value corresponding to a first value stored therein; a second storage unit having a second resistance value corresponding to a second value stored therein, wherein the second resistance value and the second value are inverse values of the first resistance value and the first value, respectively; and a current control unit to supply, during a read operation, read currents corresponding to the first and the second resistance values, and supply, during a write operation, a switching current in a direction that depends on data to be written.

In some implementations, the semiconductor memory unit further includes: a bit line coupled to the first storage unit; a bit line bar coupled to the second storage unit; and a word line coupled to receive a voltage for activating the first and second storage units.

In some implementations, the current control unit includes: a first current control unit coupled to the first and second storage units and sinking, during the read operation, the read currents of the first and second storage units; and a second current control unit coupled to the bit line and the bit line bar, providing, during the read operation, the read currents to the first and second storage units, and passing, during the write operation, the switching current flowing through the first and the second storage units.

In some implementations, during the read operation, data is read based on a comparison between the read currents flowing in the first and the second storage units.

In some implementations, during the write operation, the first and second storage units have different resistance values when the switching current flows between the bit line and the bit line bar.

In another aspect, an electronic device is provided to comprise a semiconductor memory unit which includes storage cells, each storage cell including: a first line; a second line; and a first variable resistance element and a second variable resistance element that are arranged between the first line and the second line, each of the first and the second variable resistance elements exhibits different first and second resistance values for storing either first data or second data, wherein the first and the second variable resistance elements store opposite data of the first and second data, respectively, when a write operation is performed to store a particular data in the storage cell.

In some implementations, the semiconductor memory unit further includes an access control unit providing a switching current to a storage cell only when data to be written to the corresponding storage cell during the write operation is different from data currently stored in the corresponding storage cell.

In some implementations, the semiconductor memory unit further includes an amplification unit that is coupled to the first line and the second line and drives the first line and the second line with a first voltage and a second voltage, respectively, wherein the second voltage is an inverse of the first voltage.

In another aspect, an electronic device is provided to comprise a semiconductor memory unit which include storage cells, each storage including: a first line; a second line; and a first variable resistance element and a second variable resistance element arranged between the first line and the second line in such a manner that a switching current flows therethrough in opposite directions during a write operation, each variable resistance element exhibiting different resistance values for storing different data.

In some implementations, resistance of each variable resistance element changes depending on a direction of the switching current.

Those and other aspects of the disclosed technology and their implementations and variations are described in greater detail in the drawings, the description and the claims.

### BRIEF DESCRIPTION OF THE DRAWINGS

FIG. 1 is a diagram illustrating an implementation of a magnetic tunnel junction (MTJ) which is one of structures having two magnetic layers and a tunnel barrier layer interposed therebetween.

FIGS. 2A and 2B are diagrams for explaining the principle that data is stored in a variable resistance element.

FIG. 3 is a configuration diagram of a memory circuit (device) including variable resistance elements.

FIG. 4A is a configuration diagram of a memory circuit (device) which includes a storage cell having two variable resistance elements.

FIG. 4B is a configuration diagram of a memory circuit (device) in which two variable resistance elements have different resistance values depending on a switching current flowing therethrough.

FIG. 5 is a configuration diagram of a memory circuit (device) including variable resistance elements.

FIG. 6 is a configuration diagram of a memory circuit (device) including variable resistance elements.

FIG. 7 shows an example of a configuration diagram of a microprocessor implementing memory circuitry based on the disclosed technology.

FIG. 8 shows an example of a configuration diagram of a processor implementing memory circuitry based on the disclosed technology.

FIG. 9 shows an example of a configuration diagram of a system implementing memory circuitry based on the disclosed technology.

FIG. 10 shows an example of a configuration diagram of a data storage system implementing memory circuitry based on the disclosed technology.

FIG. 11 shows an example of a configuration diagram of a memory system implementing memory circuitry based on the disclosed technology.

### DETAILED DESCRIPTION

Various examples and implementations of the disclosed technology are described below in detail with reference to the accompanying drawings.

Semiconductor devices in accordance with implementations may include variable resistance elements. The variable resistance element may exhibit a variable resistance characteristic and include a single layer or multilayer. For example, the variable resistance element may include a material used for RRAM, PRAM, MRAM, FRAM and the like, for example, a chalcogenide-based compound, a transition metal compound, a ferroelectric material, a ferromagnetic material or the like. However, the present implementations are not limited thereto. The variable resistance element may include any materials as long as the materials have a variable resistance characteristic of which resistance state is switched between different resistance states according to a voltage or current applied across the materials.

More specifically, the variable resistance element may include a metal oxide. The metal oxide may include a transition metal oxide such as nickel (Ni) oxide, titanium (Ti) oxide, hafnium (Hf) oxide, zirconium (Zr) oxide, tungsten (W) oxide, or cobalt oxide (Co) and a perovskite-based material such as STO (SrTiO) or PCMO (PrCaMnO). Such a variable resistance element may exhibit a characteristic of switching between different resistance states through formation or disappearance of a current filament, caused by behavior of vacancies.

Furthermore, the variable resistance element may include a phase change material. The phase change material may include, for example, a chalcogenide-based material such as GST (Ge—Sb—Te). The variable resistance element may be stabilized into any one of a crystalline state and an amorphous state by heat, thereby exhibiting a characteristic of switching between different resistance states.

Furthermore, the variable resistance element may include a structure having two magnetic layers and a tunnel barrier layer interposed therebetween. The magnetic layer may be formed of NiFeCo or CoFe, and the tunnel barrier layer may be formed of Al₂O₃. The variable resistance element may exhibit a characteristic of switching between different resistance states according to the relative magnetization directions of the magnetic layers. For example, the variable resistance element may have a low resistance state when the magnetization directions of the two magnetic layers are parallel to each other, and have a high resistance state when the magnetization directions of the two magnetic layers are anti-parallel to each other.

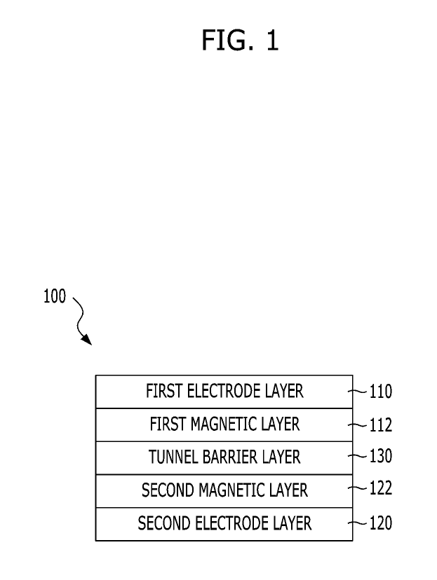

FIG. 1 is a diagram illustrating an implementation of a magnetic tunnel junction (MTJ) which is one of structures having two magnetic layers and a tunnel barrier layer interposed therebetween.

As illustrated in FIG. 1, the MTJ 100 includes a first electrode layer 110 serving as a top electrode, a second electrode layer 120 serving as a bottom electrode, a pair of first and second magnetic layers 112 and 122, and a tunnel barrier layer 130 formed between the pair of magnetic layers 112 and 122.

The first magnetic layer 112 may include a free ferromagnetic layer of which the magnetization direction is varied according to the direction of a current applied to the MTJ 100, and the second magnetic layer 122 may include a pinned ferromagnetic layer of which the magnetization direction is pinned.

The MTJ 100 of which the resistance value is changed according to the direction of the current stores a data bit value of “0” (a low data bit value) or “1” (a high data bit value).

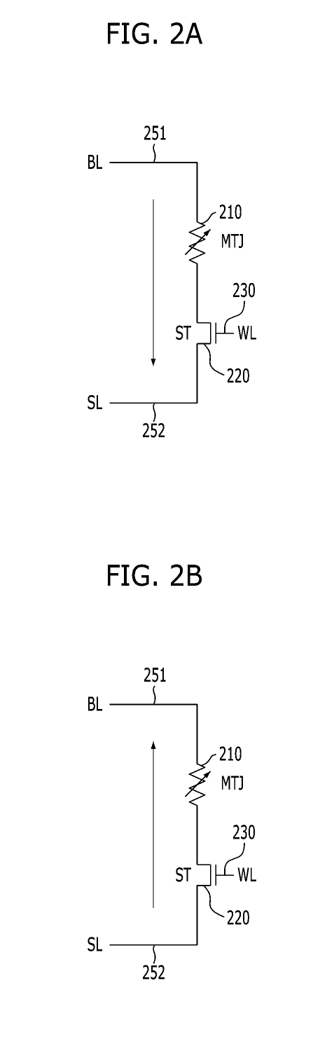

FIGS. 2A and 2B are diagrams for explaining the principle that data is stored in a variable resistance element 210. The variable resistance element 210 may include the MTJ 100 described with reference to FIG. 1. A selecting or switching element 220 is electrically coupled to one side of the MTJ 100 in series to turn on or off the electrical path to the MTJ 100 to select or de-select the MTJ 100, respectively. When the selecting element 220 is turned on, the driving circuit for driving the MTJ 100 can direct a current through the MTJ 100 in two opposite directions as illustrated in FIGS. 2A and 2B, respectively. The selecting element 220 can be implemented by various circuit elements or in various circuit configurations to provide the desired electrical switching operation in turning on or off the electrical path to the MTJ 100 and may be, e.g., a transistor or a diode. In the examples illustrated, the selecting element 220 is shown as a transistor.

FIG. 2A is a diagram for explaining the principle that a low data bit value is stored in the variable resistance element 210. In order to select the variable resistance element 210 in which data is to be stored, a word line 230 that is designated to a variable resistance element 210 is coupled to the corresponding selecting element 220 by, e.g., being connected to the gate of a transistor as the selecting element 220. As shown in FIG. 2A, the voltage of the word line 230 may be enabled to turn on the transistor 220. Then, when a current flows from one end 251 toward the other end 252, that is, from the first electrode layer 110 serving as the top electrode to the second electrode layer 120 serving as the bottom electrode of the MTJ 100 in FIG. 1 (arrow direction), the magnetization direction of the first magnetic layer 110 corresponding to the free magnetic layer may become parallel to the magnetization direction of the second magnetic layer 122 corresponding to the pinned magnetic layer. In this case, the variable resistance element 210 may have a low resistance state. When the variable resistance element 210 has a low resistance state, it may be defined that a low data bit value “0” is stored in the variable resistance element 210.

FIG. 2B is a diagram for explaining the principle that a high data bit value “1” is stored in the variable resistance element 210. Similarly, the word line 230 coupled to the selecting transistor 220 for the variable resistance element 210 may be activated to turn on the transistor 220. Then, when a current flows from the other end 252 to the one end 251, that is, from the second electrode layer 120 to the first electrode layer 110 (arrow direction), the magnetization direction of the first magnetic layer 112 may become anti-parallel to the magnetization direction of the second magnetic layer 122. In this case, the variable resistance element 210 may have a high resistance state. When the variable resistance element 210 has a high resistance state, it may be defined that high data is stored in the variable resistance element 210.

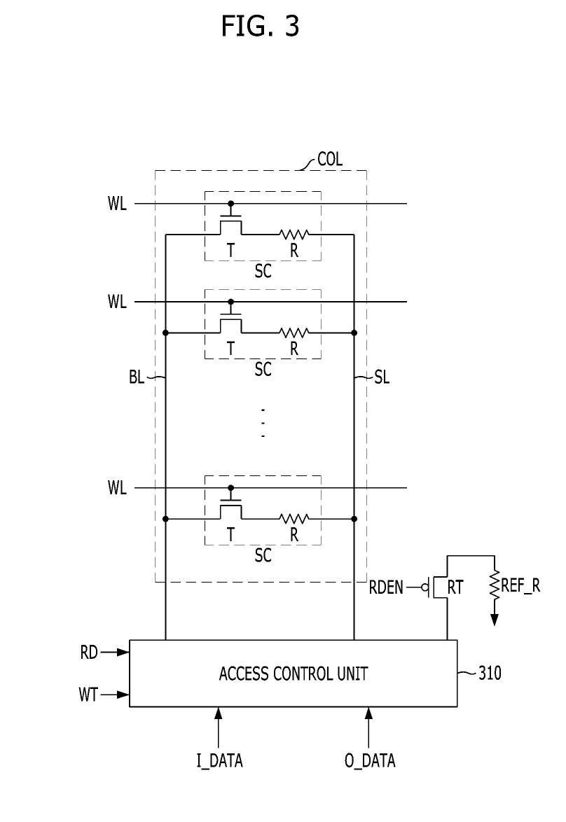

FIG. 3 is a configuration diagram of an example of a memory circuit or device including variable resistance elements.

As illustrated in FIG. 3, the memory may include a column COL, a reference resistance element REF_R, and an access control unit 310. The column COL may include a plurality of storage cells SC.

The column COL may include a bit line BL, a source line SL, and a plurality of storage cells SC coupled between the bit line BL and the source line SL. Each of the storage cells SC may include a variable resistance element R of which the resistance value is changed in response to a switching current flowing across the variable resistance element R and a selecting element T which is coupled to one end of the variable resistance element R and is turned on when a corresponding word line WL coupled to the selecting element T is activated. The bit line BL and the source line SL may be coupled to the access control unit 310.

The variable resistance element R may have a first state having a first resistance value and a second state having a second resistance value higher than the first resistance value. The first state may correspond to the above-described low resistance state, and the second state may correspond to the above-described high resistance state. The first state of the variable resistance element R may be defined as a state in which a low data bit value “0” is stored, and the second state of the variable resistance element R may be defined as a state in which a high data bit value “1” is stored. Alternatively, the first state of the variable resistance element R may be defined as a state in which the high data bit value “1” is stored, and the second state of the variable resistance element R may be defined as a state in which the low data bit value “0” is stored.

The reference resistance element REF_R may have a resistance value between the first and second resistance values of the variable resistance element R, and may be coupled to the access control unit 310 through a coupling element RT (e.g., a transistor as shown) which is turned on or off in response to a read enable signal RDEN which is activated during a read operation.

The access control unit 310 may provide a switching current in a direction which is determined by data I_DATA to be written into a selected storage cell SC when a write command WT is activated. For example, the access control unit 310 may control the switching current to flow from the source line SL to the bit line BL through the selected storage cell SC when low data is written, and control the switching current to flow from the bit line BL to the source line SL through the selected storage cell SC when high data is written.

The access control unit 310 may compare the resistance value of the variable resistance element R of the selected storage cell SC to the resistance value of the reference resistance element REF_R, read data stored in the selected storage cell SC, and output the read data as data O_DATA, when a read command RD is activated. For example, when the low resistance state corresponds to a state in which the low data bit value “0” is stored and the high resistance state corresponds to a state in which high data bit value “1” is stored, the access control unit 310 may output the low data bit value “0” as the data O_DATA in case where the resistance value of the variable resistance element R is smaller than the resistance value of the reference resistance value REF_R, and output the high data bit value “0” as the data O_DATA in case where the resistance value of the variable resistance element R is greater than the resistance value of the reference resistance value REF_R.

During the read operation, a read margin may be set to a significant large value to ensure a reliable read operation, e.g., about one half of a difference between the first and second resistance values. If the read margin decreases, the number of errors may increase or read errors may be more likely to occur, thus degrading the reliability and performance of the memory circuit or device. Furthermore, as the read margin decreases, a sufficient amount of time may be required for reading data in order to reduce the number of errors. Thus, the read speed may decrease.

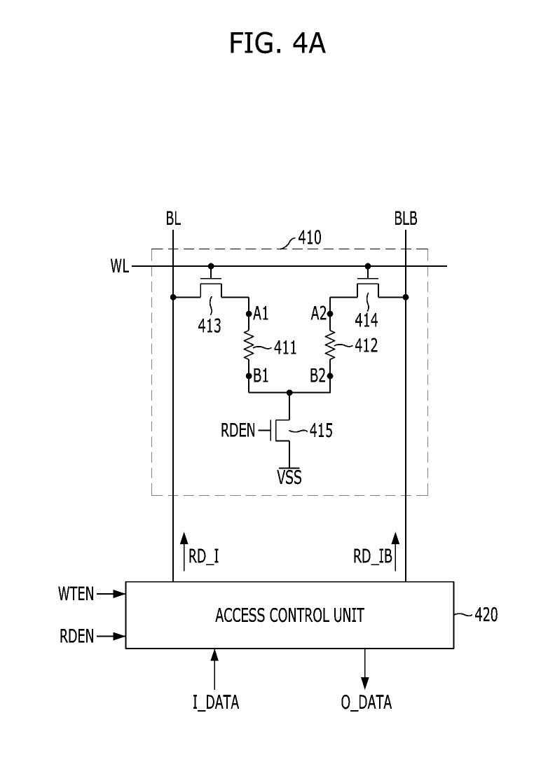

FIG. 4A is a configuration diagram of an example of a memory circuit or device which includes a storage cell 410 having two variable resistance elements 411 and 412.

As illustrated in FIG. 4A, the memory circuit may include a storage cell 410, a bit line BL, a bit line bar BLB, a word line WL, and an access control unit 420.

Referring to FIG. 4A, the storage cell 410 may include a first variable resistance element 411, a second variable resistance element 412, a first selecting element 413 coupled to a first end of the first able resistance element 411, and a second selecting element 414 coupled a first end of the second variable resistance element 412. The second ends of the first and second variable resistance elements 411 and 412 are connected together to a sinking element 415 which is a transistor. The storage cell 410 illustrated in FIG. 4A may store, for example, one-bit data.

The variable resistance elements 411 and 412 may be switched to have a first resistance value or second resistance value according to the direction of a switching current flowing therethrough. For example, the variable resistance element 411 may be switched to have a first resistance value when the switching current flows in a direction from B1 to A1 and switched to have a second resistance value when the switching current flows in a direction from A1 to B1. Similarly, the variable resistance element 412 may be switched to have a first resistance value when the switching current flows in a direction from B2 to A2 and switched to have a second resistance value when the switching current flows in a direction from tA2 to B2.

The storage cell 410 may store either a first or second value. In one implementation, the first value and the second value may indicate high data and low data, respectively. Alternatively, in another implementation, the first value and the second value may indicate low data and high data, respectively. In the example that is described below, it is assumed that the first value and the second value indicate low data and high data, respectively.

The storage cell 410 may be arranged between the bit line BL and the bit line bar BLB, and selected in response to the voltage applied to a corresponding word line WL. The bit line BL may transmit the same value of data stored in the storage cell 410, and the bit line bar BLB may transmit the opposite value of data stored in the storage cell 410. The first selecting element 413 may have three terminals that are coupled to the first selecting element 413, the first variable resistance element 411, and the word line WL, respectively. For example, one terminal is coupled to the bit line BL, the other terminal is coupled to A1 of the first variable resistance element 411, and another terminal that functions as the gate of the first selecting element 413 is coupled to the word line WL. The second selecting element 414 may have three terminals coupled to the second selecting element 414, the second variable resistance element 412, and the word line WL, respectively. For example, one terminal is coupled to the bit line bar BLB, the other terminal is coupled to A2 of the second variable resistance element 412, and another terminal that functions as the gate of the second selecting element 414 is coupled to the word line WL.

The sinking element 415 may have three terminals. One terminal of the sinking element 415 is coupled to both B1 of the first variable resistance element 411 and B2 of the second variable resistance element 412. The other terminal of the sinking element 415 is configured to receive a ground voltage VSS. Another terminal of the sinking element 415 that functions as the gate of the sinking element 415 is configured to receive a read enable signal RDEN which is activated during a read operation. The sinking element 415 may be turned on when the read enable signal RDEN is activated to supply the ground voltage VSS to the terminal B1 of the first variable resistance element 411 and the terminal B2 of the second variable resistance element 412.

During a write operation, when a write enable signal WTEN is activated, a word line WL is selected and activated. Accordingly, the read enable signal RDEN is deactivated, the selecting elements 413 and 414 may be turned on, and the sinking element 415 may be turned off. The access control unit 420 may pass a switching current to the storage cell 410 in a direction determined by input data I_DATA, when the write enable signal WTEN is activated. When the first value of data (low data) is written to the storage cell 410, the access control unit 420 may pass the switching current in a direction from the bit line bar BLB to the bit line BL. When the second value of data (high data) is written to the storage cell 410, the access control unit 420 may pass the switching current in a direction from the bit line BL to the bit line bar BLB. In the former case, the first variable resistance element 411 may be switched to have the first resistance value (switching current flows from B1 to A1), and the second variable resistance element 412 may be switched to have the second resistance value (switching current flows from A2 to B2). In the latter case, since the switching current flows in the opposite direction to the former case, the first variable resistance element 411 may be switched to have the second resistance value, and the second variable resistance element 412 may be switched to have the first resistance value.

When data is written to the storage cell 410 during the write operation, the switching currents flow in the opposite directions in the first and second variable resistance elements 411 and 412. Thus, during the write operation, the first and second variable resistance elements 411 and 412 may be switched to have different resistance values. For example, when the first value (low data) is stored in the storage cell 410, the first and second variable resistance elements 411 and 412 may have the first and second resistance values, respectively, and when the second value (high data) is stored in the storage cell 410, the first and second variable resistance elements 411 and 412 may have the second and first resistance values, respectively.

During a read operation, the word line WL and the read enable signal RDEN are activated, and the selecting elements 413 and 414 and the sinking element 415 may be turned on. When the sinking element 415 is turned on, the ground voltage VSS may be supplied to the B1 of the first variable resistance element 411 and B2 of the second variable resistance element 412. When the read enable signal RDEN is activated, the access control unit 420 controls a first read current RD_I and a second read current RD_IB. For example, the access control unit 420 may pass a first read current RD_I flowing from the bit line BL to the VSS terminal through the first variable resistance element 411, and pass a second read current RD_IB flowing from the bit line bar BLB to the VSS terminal through the second variable resistance value 412.

The amount of the first read current RD_I and the second read current RD_IB may correspond to the resistance values of the first variable resistance element 411 and the second variable resistance element 412, respectively. The access control unit 420 may compare the resistance values of the variable resistance elements R1 and R2 using the read currents RD_I and RD_IB. Alternatively, the access control unit 420 may compare the resistance values of the variable resistance elements R1 and R2 using voltages applied across the variable resistance elements R1 and R2 when the read currents RD_I and RD_IB flow through variable resistance elements R1 and R2, respectively. The access control unit 420 may output the value stored in the storage cell 410 as data O_DATA.

In the case of the storage cell 310 of FIG. 3, the resistance value of the variable resistance element having the first or second resistance value is compared to the resistance value of the reference resistance element having a resistance value between the first and second resistance values. Thus, the margin may correspond to one half of a difference between the first and second resistance values. On the other hand, in the case of the storage cell 410 of FIG. 4A, the resistance value of the first variable resistance element having the first or second resistance value is compared to the resistance value of the second variable resistance element having a different resistance value from the first variable resistance element 411 between the first and second resistance values. Thus, the margin may correspond to a difference between the first and second resistance values. Therefore, the margin may be increased, and the time required for sensing data during the read operation may be reduced. As a result, the memory circuit or device including the storage cell 410 of FIG. 4A may perform a high-speed operation.

FIG. 4B is a configuration diagram of an example of a memory circuit or device which controls a switching current such that two variable resistance elements 411 and 412 have different resistance values.

As illustrated in FIG. 4B, the memory circuit may include a first storage unit 430A containing the first variable resistance element 411, a second storage unit 430B containing the second variable resistance element 412, a current control unit 440, a bit line BL, a bit line bar BLB, and a word line WL.

Referring to FIG. 4B, Each of the first and second storage units 430A and 430B may have a resistance value corresponding to a value stored therein. For example, when the first and second storage units 430A and 430B store the first value (for example, low data), the first and second storage units 430A and 430B may have a first resistance value, and when the first and second storage units 430A and 430B store the second value (for example, high data), the first and second storage units 430A and 430B may have a second resistance value higher than the first resistance value. In FIG. 4B, the first storage unit 430A may store the inverse value of the value stored in the second storage unit 430B. The first and second storage units 430A and 430B may be controlled to store opposite values by controlling the switching current that is provided from the current control unit 440.

The first selecting element 413 of the first storage unit 430A may be turned on or off in response to the voltages of the first variable resistance element 411 and the word line WL. The second selecting element 414 of the second storage unit 430B may be turned on or off in response to the voltages of the second variable resistance element 412 and the word line WL. One end of the first storage unit 430A may be coupled to the bit line BL, and one end of the second storage unit 430B may be coupled to the bit line bar BLB.

The current control unit 440 may be coupled to the bit line BL, the bit line bar BLB and the first and second storage units 430A and 430B so as to control the magnitudes and directions of currents flowing in the first and second storage units 430A and 430B.

During a read operation in which a read enable signal RDEN is activated, the current control unit 440 may supply a read current corresponding to the value stored in the first storage unit 430A to the first storage unit 430A through the bit line BL, and supply a read current corresponding to the value stored in the second storage unit 430B to the second storage unit 430B through the bit line bar BLB. The magnitudes of the read currents flowing in the first and second storage units 430A and 430B may correspond to the resistance values of the first and second storage units 430A and 430B. The magnitudes of the read currents flowing in the first and second storage units 430A and 430B may be compared to read data, and the read data may be outputted as data O_DATA.

During a write operation in which a write enable signal WTEN is activated and received by the access control unit, the current control unit 440 may supply a switching current between the bit line BL and the bit line bar BLB such that the first and second storage units 430A and 430B have different resistance values. In FIG. 4A, when the current control unit 440 supplies a switching current from the bit line BL to the bit line bar BLB and when the current control unit 440 supplies a switching current from the bit line bar BLB to the bit line BL, the first and second variable resistance elements 411 and 412 may be switched to have different resistance values from each other. The current control unit 440 may supply or direct a switching current in a direction determined by the input data I_DATA.

The current control unit 440 may include a first current control unit 441 and a second current control unit 442. The first current control unit 441 may be commonly coupled to one common end of the first and second storage units 430A and 430B where the first current control unit 441 may sink the read currents of the first and second storage units 430A and 430B into the ground voltage terminal VSS during a read operation. The first current control unit 441 may be disabled during a write operation. The second current control unit 442 may be coupled to the bit line BL and bit line bar BLB. The first current control unit 441 may provide read currents to the first and second storage units 430A and 430B during a read operation, and supply a switching current between the bit line BL and the bit line bar BLB in a direction determined by the input data I DATA during a write operation.

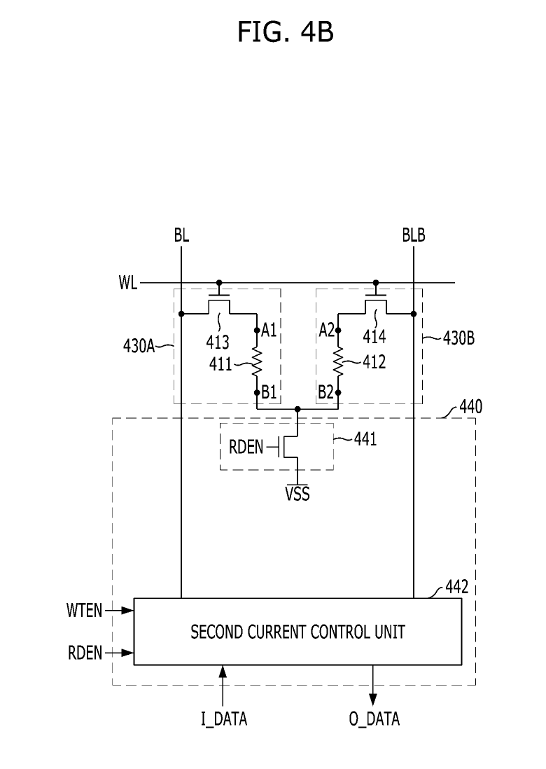

FIG. 5 is a configuration diagram of an example of a memory circuit or device including variable resistance elements.

As illustrated in FIG. 5, the memory circuit may include a plurality of columns COL0 to COLM, a plurality of word lines WL0 to WLN, a plurality of amplification units 510_0 to 510_M, a word line control unit 520, and an access control unit 530. Each of the columns COL0 to COLM may include one or more storage cells SC, each including the storage cell 410 described above with reference to FIG. 4.

Referring to FIG. 5, the plurality of columns COL0 to COLM may include bit lines BL0 to BLM, bit line bars BLB0 to BLBM, and one or more storage cells SC coupled between one of the bit lines BL0 to BLM and one of the bit line bars BLB0 to BLBM. Each of the bit line BL0 to BLM may transmit the same data as data stored in a storage cell SC, and each of the bit line bars BLB0 to BLBM may transmit the opposite data of data stored in a storage cell SC.

A storage cell SC in each column (COL0 . . . COLM) may include a first variable resistance element R1, a second variable resistance element R2, a first selecting element S1, a second selecting element S2, and a sinking element SI. In one implementation, the first variable resistance element R1, the second variable resistance element R2, the first selecting element S1, the second selecting element S2, and the sinking element SI may correspond to the first variable resistance element 411, the second variable resistance element 412, the first selecting element 413, the second selecting element 414, and the sinking element 415 of FIG. 4A. The coupling and operations of the storage cell SC in FIG. 5 are the same as described with reference to FIGS. 4A and 4B. A column in FIG. 5 may include multiple storage cells SC that are coupled between a pair of a bit line and a bit line bar for the corresponding column and are coupled to respective word lines.

The plurality of amplification units 510_0 to 510_M may correspond to the respective columns COL0 to COLM, one amplification unit per column as shown in the example in FIG. 5. Each of the amplification units 510_0 to 510_M may be coupled between the bit line and the bit line bar of the corresponding column. Each of the amplification units 510_0 to 510_M may provide different voltages to the bit line and the bit line bar from each other. For example, the amplification unit can provide the inverse voltage of a voltage corresponding to data of the bit line to the bit line bar, and provide the inverse voltage of a voltage corresponding to data of the bit line bar to the bit line. For example, when the data of the bit line is high data, the amplification unit may drive the bit line bar to a voltage corresponding to low data in response to the data of the bit line, and when the data of the bit line is low data, the amplification unit may drive the bit line bar to a voltage corresponding to high data in response to the data of the bit line. As such, the amplification unit drives the bit line and the bit line bar to have opposite voltages from each other.

The amplification units 510_0 to 510_M may perform the above-described driving operation, when the write enable signal WTEN is activated during a write operation or the read enable signal RDEN is activated during a read operation. Each of the amplification units 510_0 to 510_M may have a first voltage terminal VA configured to receive a voltage required for the read operation or write operation and a second voltage terminal VB configured to receive a ground voltage VSS. The amplification units 510_0 to 510_M may be designed to be enabled only when one of the read operation and the write operation is performed.

As illustrated by the insert on the right hand side of FIG. 5, each of the amplification units 510_0 to 510_M may include a plurality of NMOS transistors N1, N2, and N3 and a plurality of PMOS transistors P1 and P2. The amplification units 510_0 to 510_M may be enabled or disabled in response to an enable signal EN which is activated when the write enable signal WTEN or the read enable signal RDEN is activated. The NMOS transistor N3 may be turned on when the enable signal EN is activated to cause the amplification unit to drive the bit line BL and bit line bar BLB. The NMOS transistor N1 may be turned on when the voltage of the bit line bar BLB corresponds to high data to drive the bit line BL to the voltage of the second voltage terminal VB. The NMOS transistor N2 may be turned on when the voltage of the bit line BL corresponds to high data to drive the bit line bar BLB to the voltage of the second voltage terminal VB. The PMOS transistor P1 may be turned on when the voltage of the bit line bar BLB corresponds to low data to drive the bit line BL to the voltage of the first voltage terminal VA. The NMOS transistor N2 may be turned on when the voltage of the bit line BL corresponds to low data to drive the bit line bar BLB to the voltage of the first voltage terminal VA.

The word line control unit 520 may activate a selected word line among the plurality of word lines WL0 to WLN in response to word line select information SEL_WL<0:A>. The word line control unit 520 may apply a voltage to the selected word line to turn on the selecting elements S1 and S2 coupled thereto.

The access control unit 530 may provide or supply a proper current to a selected storage cell SC during a read operation or write operation. The access control unit 530 may provide or supply a first read current RD_I and a second read current RD_IB to the selected storage cell SC during the read operation. The access control unit 530 may read data stored in the storage cell SC using the read currents RD_I and RD_IB or voltages applied across the variable resistance elements. Furthermore, the access control unit 530 may supply a switching current in a direction determined by data to be written to the selected storage cell SC during the write operation. The access control unit 530 may switch states of the first and second variable resistance elements R1 and R2 of the selected storage cell SC such that the first and second variable resistance elements R1 and R2 have a proper resistance value.

The access control unit 530 may include a plurality of write control units 531_0 to 531_M and a plurality of read control units 532_0 to 532_M. The plurality of write control units 531_0 to 531_M may be selected in response to column select information SEL_COL<0:M>, when the write enable signal WTEN is activated. The selected write control units 531_0 to 531_M may supply a switching current to the corresponding bit lines BL0 to BLM and the corresponding bit line bars BLB0 to BLBM in a direction determined by input data IDATA<0:M>. For example, when the input data IDATA<0:M> has low value, the write control units 531_0 to 531_M may drive the bit lines BL0 to BLM and the bit line bars BLB0 to BLBM such that currents flow from the bit lines BL0 to BLM to the bit line bars BLB0 to BLBM. When the input data IDATA<0:M> has high value, the write control units 531_0 to 531_M may drive the bit lines BL0 to BLM and the bit line bars BLB0 to BLBM such that currents flow from the bit line bars BLB0 to BLBM to the bit lines BL0 to BLM.

The plurality of read control units 532_0 to 532_M may be selected in response to the column select information SEL_COL<0:M>, when the read enable signal RDEN is activated. The selected read control units 532_0 to 532_M may supply read current to the corresponding bit lines BL0 to BLM and the corresponding bit line bars BLB0 to BLBM. For example, each of the selected read control units 532_0 to 532_M may apply a higher voltage than the ground voltage VSS to the bit line and the bit line bar. In other implementations, each of the selected read control units 532_0 to 532_M may be coupled to a constant current source such that the first read current RD_I flows from the bit line to the first variable resistance element R1 and second read current RD_IB flows from the bit line bar to the second variable resistance element R2.

Each of the plurality of read control units 532_0 to 532_M may compare the resistance values of the first and second resistance elements R1 and R2 using the read currents RD_I and RD_IB or voltages applied across the variable resistance elements R1 and R2, and output data stored in the storage cell SC as data ODATA.

The read control unit can be operated to use the read current RD_I and RD_IB to compare the resistance values of the first and second variable resistance elements R1 and R2. If the first read current RD_I is smaller than the second read current RD_IB, the resistance values of the first and second variable resistance elements R1 and R2 may be set to the first and second resistance values, respectively. If the first read current RD_I is not smaller than the second read current RD_IB, the resistance values of the first and second variable resistance elements R1 and R2 may be set to the second and first resistance values, respectively. In another implementation, the read control unit uses voltages applied across the variable resistance elements R1 and R2 to compare the resistance values of the first and second resistance elements R1 and R2. Assuming that the first read current RD_I is equal to the second read current RD_IB. If the voltage applied across the first variable resistance element R1 is smaller than the voltage applied across the second variable resistance element R2, the resistance values of the first and second variable resistance elements R1 and R2 may be set to the first and second resistance values, respectively. If the voltage applied across the first variable resistance element R1 is not smaller than the voltage applied across the second variable resistance element R2, the resistance values of the first and second variable resistance elements R1 and R2 may be set to the second and first resistance values, respectively.

When the write enable signal WTEN is activated, a plurality of write enable elements WC may electrically couple the plurality of write control units 531_0 to 531_M to the corresponding bit lines BL0 to BLM and the corresponding bit line bars BLB0 to BLBM. When the read enable signal RDEN is activated, a plurality of read enable elements RC may electrically couple the plurality of read control units 532_0 to 532_M to the corresponding bit lines BL0 to BLM to the corresponding bit line bars BLB0 to BLBM.

The memory circuit or device may include two variable resistance elements in each storage cell SC, and control the two variable resistance elements to have different resistance values according to the data of the storage cell SC. Thus, read margin may be increased, and read operation speed may be improved. Furthermore, during a read or write operation, the memory circuit may additionally drive the bit lines BL0 to BLM and bit line bars BLB0 to BLBM using the amplification units 510_0 to 510_M, thereby increasing the precision and speed of the read or write operation. Furthermore, although the plurality of write control units 531_1 to 531_M drive the bit lines BL0 to BLM and bit line bars BLB0 to BLBM with a small driving force, the memory circuit can accurately control the bit lines BL0 to BLM and bit line bars BLB0 to BLBM. Thus, it is possible to reduce the size of the write control units 531_0 to 531_M.

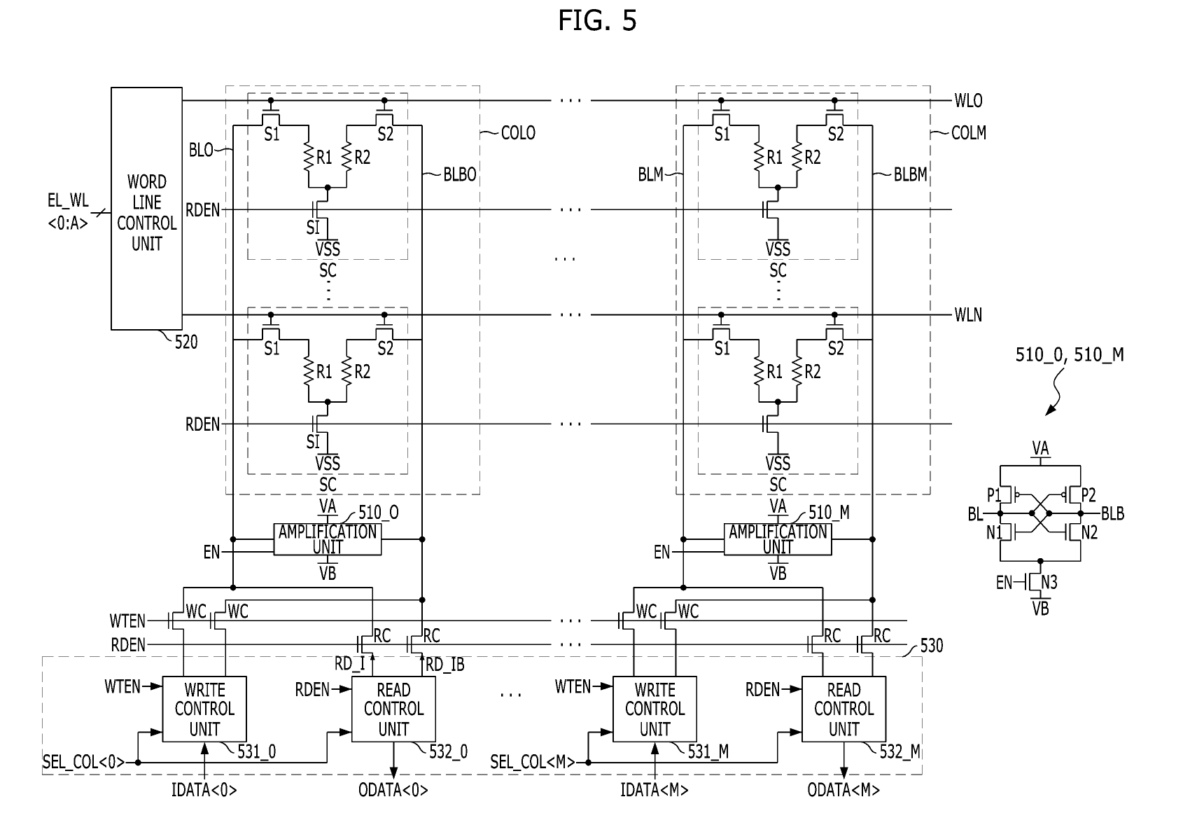

FIG. 6 is a configuration diagram of an example of a memory circuit or device including variable resistance elements.

As illustrated in FIG. 6, the memory circuit may include a plurality of column COL0 to COLM, a plurality of word lines WL0 to WLN, a plurality of comparison units 610_0 to 610_M, a word line control unit 620, and an access control unit 630. Each of the columns COL0 to COLM may include one or more storage cells SC, each including the storage cell SC described above with reference to FIG. 4. The access control unit 630 may include a plurality of write control units 631_0 to 631_M and a plurality of read control units 632_0 to 632_M.

Referring to FIG. 6, the plurality of columns COL0 to COLM, the plurality of word lines WL0 to WLN, and the word line control unit 620 may correspond to the plurality of columns COL0 to COLM, the plurality of word lines WL0 to WLN, and the word line control unit 520 of FIG. 5, respectively. Various configurations and operations of the circuit in FIG. 6 are similar to or the same as corresponding configurations and operations of the circuit in FIG. 5.

During a write operation, the memory circuit of FIG. 6 may compare data stored in a selected storage cell SC with data to be written to the selected storage cell SC. Depending on the comparison result, the memory unit of FIG. 6 may or may not supply a switching current to the selected storage cell SC. For example, when the two data are different from each other, the memory circuit of FIG. 6 supplies a switching current to the selected storage cell SC. When the two data are equal to each other, the memory circuit of FIG. 6 may not supply a switching current to the selected storage cell SC.

In order to control the switching current, during the write operation, the memory circuit may first activate the read enable signal RDEN for a preset or predetermined time period. Then, the memory circuit may control the plurality of read control units 632_0 to 632_M to drive bit lines BL0 to BLM and bit line bars BLB0 to BLBM. The data stored in the storage cell SC may be loaded into the bit lines BL0 to BLM and the bit line bars BLB0 to BLBM.

The plurality of comparison units 610_0 to 610_M may compare the data of the bit lines BL0 to BLM (or the data of the bit lines BLB0 to BLBM) with the input data IDATA<0:M>. The comparison results CMP<0:M> may be handled as outputs. For example, when the data of the bit lines BL0 to BLM are equal to the input data IDATA<0:M>, the comparison results CMP<0:M> may be deactivated. When the data of the bit lines BL0 to BLM are different from the input data IDATA<0:M>, the comparison results CMP<0:M> may be activated.

The plurality of write control units 631_0 to 631_M may be selected in response to the column select information SEL_COL<0:M> when the write enable signal WTEN is activated. The selected write control units 631_0 to 631_M may control a switching current in response to the corresponding comparison results CMP<0:M>. For example, the selected write control units 631_0 to 631_M provides the switching current to flow into the corresponding bit lines BL0 to BLM and the corresponding bit line bar BLB0 to BLBM in a direction determined by the input data IDATA<0:M> when the data stored in the storage cell SC are different from the input data IDATA<0:M>. The selected write control units 631_0 to 631_M may not drive the bit lines BL0 to BLM and the bit line bar BLB0 to BLBM such that no switching current flows into the storage cell SC, when the data stored in the storage cell SC are equal to the input data IDATA<0:M>.

The memory circuit or device in the example in FIG. 6 may include two variable resistance elements in each storage cell. The memory circuit may control the two variable resistance elements to have different resistance values according to the data of the storage cell SC. Thus, the read margin and read speed can be increased. During a write operation, the comparison units 610_0 to 610_M of the memory circuit may compare the data stored in the storage cell SC with the input data IDATA<0:M>. Only when the data stored in the storage cell SC are different from the input data IDATA<0:M> (i.e., data need to be written again), the write control units 631_0 to 631_M of the memory circuit operates to drive the bit lines BL0 to BLM and bit line bars BLB0 to BLBM. Thus, current consumption during a write operation can be reduced.

In the examples in FIGS. 5 and 6, the memory circuit in FIG. 5 includes the plurality of amplification units 510_0 to 510_M and the memory circuit in FIG. 6 includes the plurality of comparison units 610_0 to 610_M. However, it is also possible that the memory circuit may include both of the plurality of amplification units 510_0 to 510_M and the plurality of comparison units 610_0 to 610_M depending on design. Having both amplification units and comparison units in a memory circuit may enable the memory circuit to accomplish the effects that are discussed with regard to the circuits in FIGS. 5 and 6: increasing the read margin and improving the read operation speed. In addition, the accuracy and speed of the read and write operations may be increased, and the size of the plurality of write control units 531_0 to 531_M may be reduced. Furthermore, during a write operation, the current consumption may be advantageously reduced to reduce overall power consumption of the circuit.

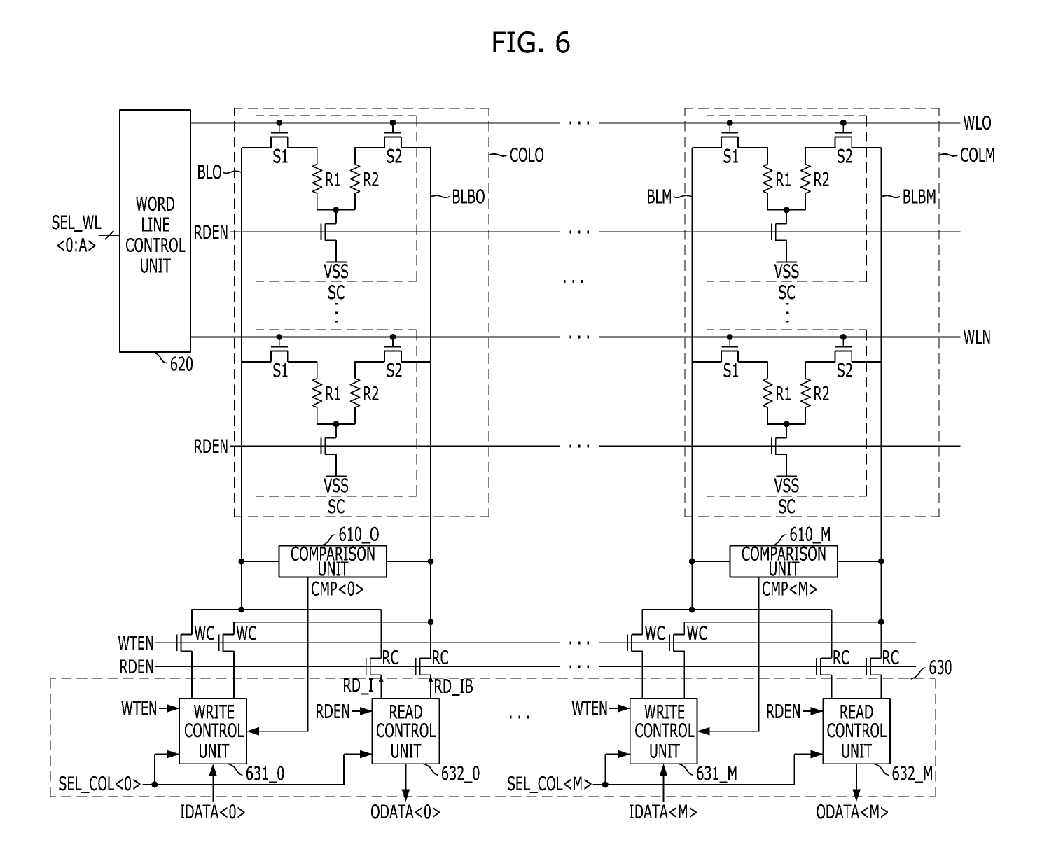

The above and other memory circuits or semiconductor devices based on the disclosed technology can be used in a range of devices or systems. FIGS. 7-11 provide some examples of devices or systems that can implement the memory circuits disclosed herein.

FIG. 7 shows an example of a configuration diagram of a microprocessor based on another implementation of the disclosed technology.

Referring to FIG. 7, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and an address where data for performing of the operations are stored.

The memory unit 1010 may include one or more of the above-described semiconductor devices in accordance with the implementations. For example, the memory unit 1010 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the memory unit 1010 may be increased, a read margin of the memory unit 1010 may be increased, and a consumption of write current of the memory unit 1010 may be reduced. Consequently, operation speed and stability of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands and controlling input and output of signals of the microprocessor, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

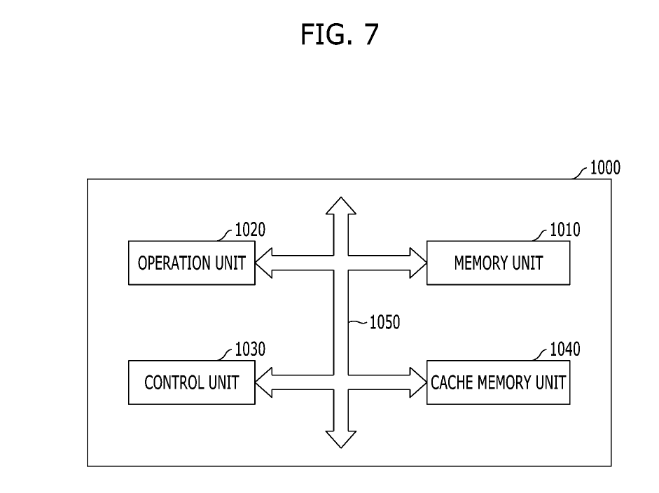

FIG. 8 is a configuration diagram of a processor based on another implementation of the disclosed technology.

Referring to FIG. 8, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and an address where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage unit 1121, a secondary storage unit 1122 and a tertiary storage unit 1123. In general, the cache memory unit 1120 includes the primary and secondary storage units 1121 and 1122, and may include the tertiary storage unit 1123 in the case where high storage capacity is required. As the occasion demands, the cache memory unit 1120 may include an increased number of storage units. That is to say, the number of storage units which are included in the cache memory unit 1120 may be changed according to a design. The speeds at which the primary, secondary and tertiary storage units 1121, 1122 and 1123 store and discriminate data may be the same or different. In the case where the speeds of the respective storage units 1121, 1122 and 1123 are different, the speed of the primary storage unit 1121 may be largest. At least one storage unit of the primary storage unit 1121, the secondary storage unit 1122 and the tertiary storage unit 1123 of the cache memory unit 1120 may include one or more of the above-described semiconductor devices in accordance with the implementations. For example, the cache memory unit 1120 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the cache memory unit 1120 may be increased, a read margin of the cache memory unit 1120 may be increased, and a consumption of write current of the cache memory unit 1120 may be reduced. Consequently, operation speed and stability of the processor 1100 may be improved.

Although it was shown in FIG. 8 that all the primary, secondary and tertiary storage units 1121, 1122 and 1123 are configured inside the cache memory unit 1120, it is to be noted that all the primary, secondary and tertiary storage units 1121, 1122 and 1123 of the cache memory unit 1120 may be configured outside the core unit 1110 and may compensate for a difference in data processing speed between the core unit 1110 and the external device. Meanwhile, it is to be noted that the primary storage unit 1121 of the cache memory unit 1120 may be disposed inside the core unit 1110 and the secondary storage unit 1122 and the tertiary storage unit 1123 may be configured outside the core unit 1110 to strengthen the function of compensating for a difference in data processing speed. In another implementation, the primary and secondary storage units 1121, 1122 may be disposed inside the core units 1110 and tertiary storage units 1123 may be disposed outside core units 1110. The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage unit 1121 of the cache memory unit 1120 may be configured in each core unit 1110 in correspondence to the number of the plurality of core units 1110, and the secondary storage unit 1122 and the tertiary storage unit 1123 may be configured outside the plurality of core units 1110 in such a way as to be shared through the bus interface 1130. The processing speed of the primary storage unit 1121 may be larger than the processing speeds of the secondary and tertiary storage unit 1122 and 1123. In another implementation, the primary storage unit 1121 and the secondary storage unit 1122 may be configured in each core unit 1110 in correspondence to the number of the plurality of core units 1110, and the tertiary storage unit 1123 may be configured outside the plurality of core units 1110 in such a way as to be shared through the bus interface 1130.The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data prepared in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory) and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), and a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device(HD audio), a high definition multimedia interface (HDMI) controller, and so on.

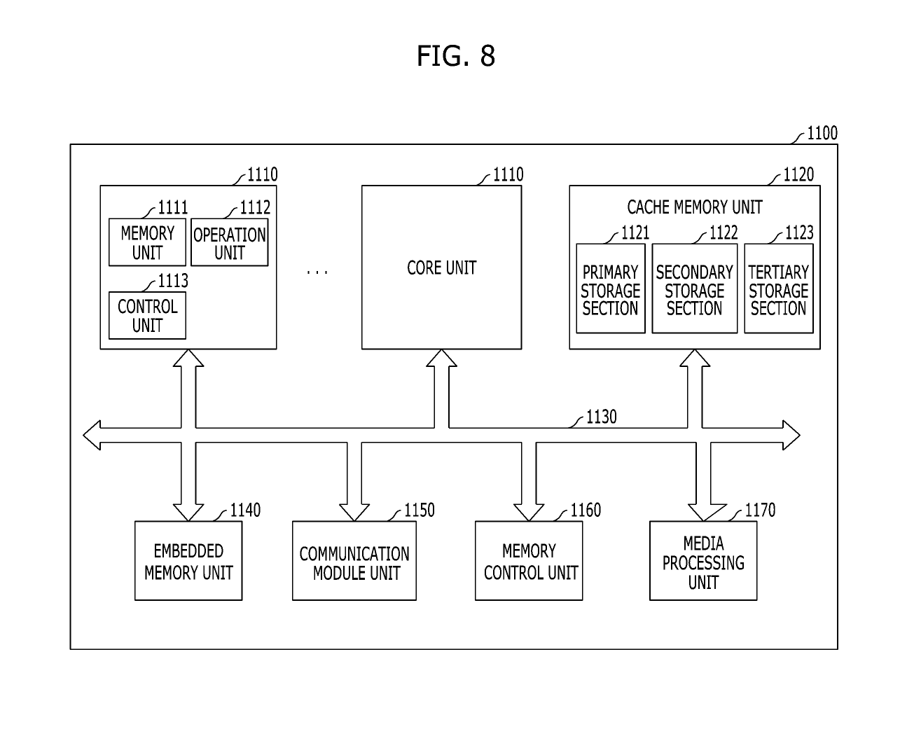

FIG. 9 is a configuration diagram of a system based on another implementation of the disclosed technology.

Referring to FIG. 9, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 decodes inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the main memory device 1220 may be increased, a read margin of the main memory device 1220 may be increased, and a consumption of write current of the main memory device 1220 may be reduced. Consequently, operation speed and stability of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the auxiliary memory device 1230 may be increased, a read margin of the auxiliary memory device 1230 may be increased, and a consumption of write current of the auxiliary memory device 1230 may be reduced. Consequently, operation speed and stability of the system 1200 may be improved.

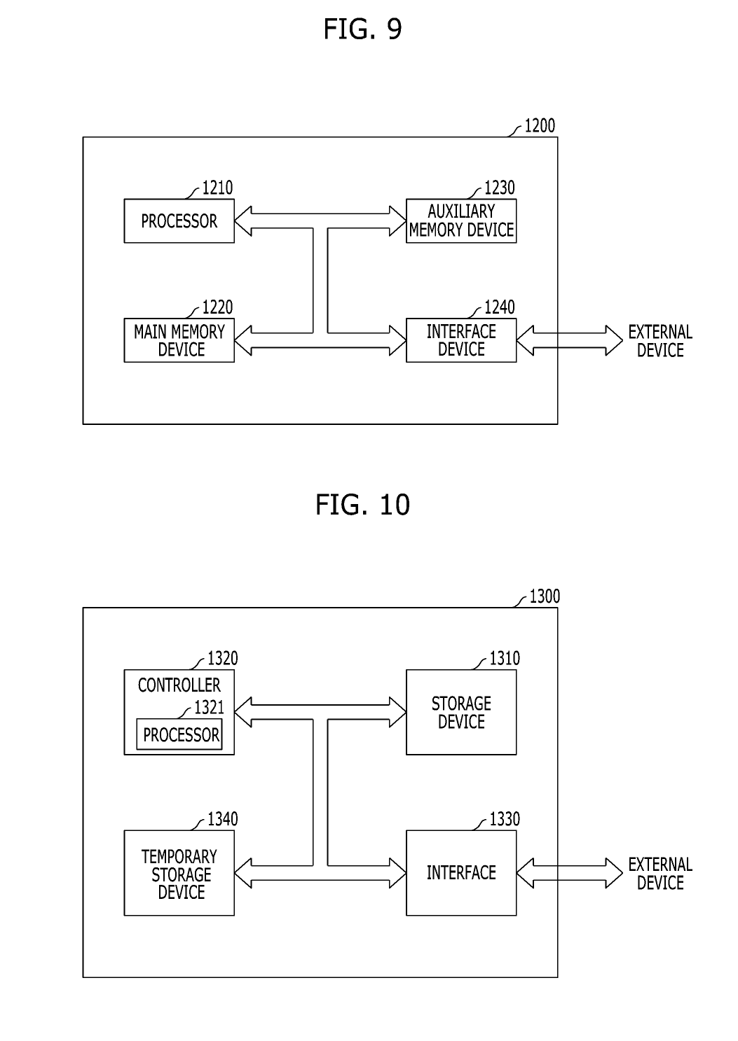

Also, the auxiliary memory device 1230 may further include a data storage system (see the reference numeral 1300 of FIG. 12) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device and so on. The communication device may include a module capable of being connected with a wired network, a module capable of being connected with a wireless network and both of them.

The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 10 is a configuration diagram of a data storage system based on another implementation of the disclosed technology.

Referring to FIG. 10, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices.

In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other. The temporary storage device 1340 can store data temporarily implementation for efficiently transferring data between the interface 1330 and the storage device 1310 according to diversifications and high performance of an interface with an external device, a controller and a system. For example, the temporary storage device 1340 implementation for temporarily storing data may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the temporary storage device 1340 may be increased, a read margin of the temporary storage device 1340 may be increased, and a consumption of write current of the temporary storage device 1340 may be reduced. Consequently, operation speed and stability of the data storage system 1300 can be improved.

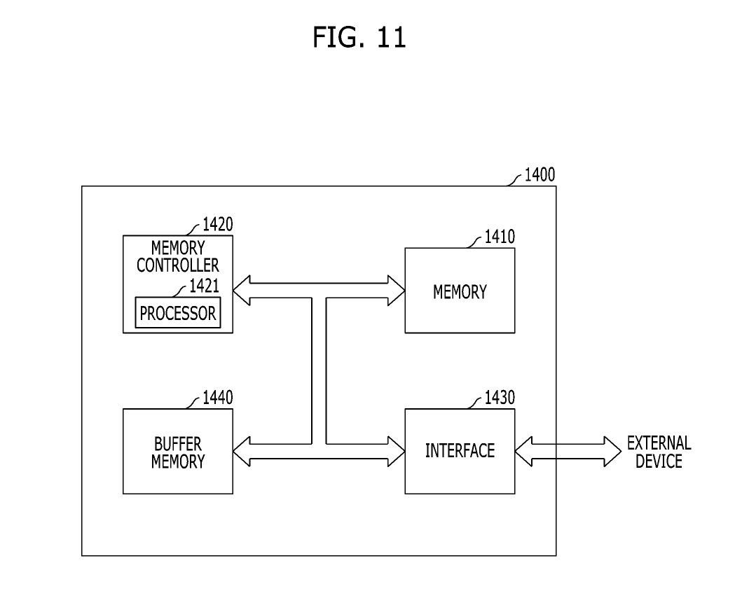

FIG. 11 is a configuration diagram of a memory system based on another implementation of the disclosed technology.

Referring to FIG. 11, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read speed of the memory 1410 may be increased, a read margin of the memory 1410 may be increased, and a consumption of write current of the memory 1410 may be reduced. Consequently, operation speed and stability of the memory system 1400 can be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 implementation may include one or more storage cells for storing data, and each of the storage cells includes: a first resistance variable element having a first resistance value when a first value is stored therein, and having a second resistance value when a second value is stored therein; and a second resistance variable element having the second resistance value when the first value is stored therein, and having the first resistance value when the second value is stored therein. Through this, a write and read operation speed of the buffer memory 1440 may be increased, a read margin of the buffer memory 1440 may be increased, and a consumption of write current of the buffer memory 1440 may be reduced. Consequently, operation speed and stability of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 7-11 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising a semiconductor memory unit,
wherein the semiconductor memory unit includes one or more storage cells for storing data, and
each of the storage cells includes:
a first resistance variable element having a first resistance value when a first value is stored therein, and having a second resistance value when a second value is stored therein; and
a second resistance variable element having the second resistance value when the first value is stored therein, and having the first resistance value when the second value is stored therein.

2. The electronic device of claim 1, wherein, during a read operation, the semiconductor memory unit compares a current flowing in the first variable resistance element with a current flowing in the second variable resistance element.

3. The electronic device of claim 1, wherein each of the first and second variable resistance elements has a resistance value which is switched between first and second resistance values when a switching current is switched between a first current direction and a second, opposite current direction when flowing through each variable resistance element.

4. The electronic device of claim 3, wherein when the first value is stored in the storage cell, the semiconductor memory unit passes the switching current in the first direction through the first variable resistance element and passes the switching current in the second, opposite direction through the second variable resistance element, and
when the second value is stored in the storage cell, the semiconductor memory unit passes the switching current in the second direction through the first variable resistance element and passes the switching current in the first direction through the second variable resistance element.

5. The electronic device of claim 1, wherein the semiconductor memory unit further includes:
one or more word lines each coupled to apply a voltage to select a corresponding storage cell among the one or more storage cells;
one or more first bit lines each coupled to one end of a corresponding storage cell among the one or more storage cells; and
one or more second bit lines each coupled to the other end of a corresponding storage cell among the one or more storage cells.

6. The electronic device of claim 1, wherein each storage cell includes:
a first selecting element coupled between the first bit line and one end of the first resistance variable element, and operable to be turned on or off in response to the voltage of a corresponding word line;
a second selecting element coupled between the second bit line and one end of the second resistance variable element, and operable to be turned on or off in response to the voltage of the corresponding word line; and
a sinking element coupled to the other ends of the first and the second variable resistance elements, and operable to be turned on or off to allow for passage a current.

7. The electronic device of claim 1, wherein during the write operation, the first and second selecting elements of a selected storage cell among the one or more storage cells are turned on and the sinking element of the selected storage cell is turned off,
when the first value is stored in the selected storage cell, the switching current flows from the second bit line to the first bit line through the selected storage cell, and
when the second value is stored in the selected storage cell, the switching current flows from the first bit line to the second bit line through the selected storage cell.

8. The electronic device of claim 1, wherein the semiconductor memory unit further includes an access control unit that provides a switching current to a selected storage cell during a write operation in a manner that the direction of the switching current changes depending on data to be written to the selected storage cell.

9. The electronic device of claim 1, wherein, during the read operation, the first and second selecting elements of a selected storage cell among the one or more storage cells are turned on and the sinking element of the selected storage cell is turned on,
a current flows between the first bit line and the source line through the selected storage cell, and
a current flows between the second bit line and the source line through the selected storage cell.

10. The electronic device of claim 1, wherein, the semiconductor memory unit further includes an access control unit, that provides, during a read operation, a first read current and a second read current flowing through the first and the second variable resistance elements, respectively, and determines data stored in the storage cell by comparing the first read current with the second read current.

11. The electronic device of claim 5, wherein the semiconductor memory unit comprises one or more amplification units each coupled between the first and second bit lines, and suitable for driving the second bit line to the inverse voltage of a voltage corresponding to data of the first bit line and driving the first bit line to the inverse voltage of a voltage corresponding to data of the second bit line.

12. The electronic device of claim 5, wherein the semiconductor memory unit further includes a write control unit suitable for driving the first and second bit lines to a voltage which is determined according to data to be written to a selected storage cell among the plurality of storage cells, and not driving the first and second bit lines when the data stored in the selected storage cell is equal to the data to be written to the selected storage cell.

13. The electronic device of claim 5, wherein the semiconductor memory unit further includes a write control unit suitable for driving the first and second bit lines to a voltage which is determined according to data to be written to a selected storage cell among the plurality of storage cells only when the data stored in the selected storage cell is not equal to the data to be written to the selected storage cell.

14. The electronic device of claim 1, wherein each of the first and second variable resistance elements includes a metal oxide, a phase change material, or a structure having two magnetic layers and a tunnel barrier layer interposed therebetween.

15. An electronic device comprising a semiconductor memory unit,
wherein the semiconductor memory unit includes:
bit lines;
bit line bars;
a plurality of word lines;
a plurality of first selecting elements each having one end coupled to a corresponding bit line, and operable to be turned on or off in response to the voltage of a corresponding word line;
a plurality of first variable resistance elements each having one end coupled to the other end of a corresponding first selecting element;
a plurality of second selecting elements each having one end coupled to a corresponding bit line bar, and operable to be turned on or off in response to the voltage of a corresponding word line; and
a plurality of second resistance variable elements each having one end coupled to the other end of a corresponding second selecting element and the other end coupled to the other end of a corresponding first resistance variable element,
wherein each of the first variable resistance elements and the second variable resistance elements has either a first resistance value or a second resistance value and the resistance value of each of the first variable resistance elements and the second variable resistance elements changes depending on a direction of a switching current flowing through each of the first variable resistance elements and the second variable resistance elements.

16. The electronic device of claim 15, wherein the semiconductor memory unit activates a selected word line among the plurality of word lines, and passes a current between the bit line and the bit line bar through first and second resistance variable elements corresponding to the activated word line, during a write operation.

17. The electronic device of claim 15, wherein, during a read operation, the semiconductor memory unit activates a selected word line among the plurality of word lines, passes a first read current between the bit line and a first variable resistance element corresponding to the activated word line, passes a second read current between the bit line bar and a second variable resistance element corresponding to the activated word line, and compares the first read current to the second read current.

18. The electronic device of claim 15, wherein the semiconductor memory unit further includes a plurality of sinking elements each coupled to a pair of first and second variable resistance elements that are located next to each other and are connected to each other, and operable to be turned on to apply a read voltage to the first resistance variable element and the corresponding paired second resistance variable element during the read operation.

19. The electronic device of claim 15, wherein the semiconductor memory unit further includes one or more amplification units each coupled between a corresponding bit line and a corresponding bit line bar, and suitable for driving the bit line bar to the opposite voltage of a voltage corresponding to data of the bit line and driving the bit line to the opposite voltage of a voltage corresponding to data of the bit line bar.

20. The electronic device of claim 15, wherein the semiconductor memory unit further includes one or more write control units suitable for driving a bit line and a bit line bar, corresponding to first and second resistance variable elements which are selected among the plurality of first resistance variable elements and the plurality of second resistance variable elements, to a voltage which is determined according to data to be written to the selected first and second resistance variable elements, and not driving the bit line and the bit line bar corresponding to the selected first and second resistance variable elements when data stored in the selected first and second resistance variable elements are equal to data to be written to the selected first and second resistance variable elements.
